(19) United States
(12) Patent Application Publication
(10) Pub. No.: US 2026/0282506 A1
(43) Pub. Date: Sep. 17, 2026

(54) EPITAXIAL LAYER DEPOSITION FOR SEMICONDUCTOR DEVICES

(71) Applicant: Applied Materials, Inc., Santa Clara, CA (US)

(72) Inventors: Ashish Pal, San Ramon, CA (US); Benjamin Colombeau, San Jose, CA (US); El Mehdi Bazizi, San Jose, CA (US)

(73) Assignee: Applied Materials, Inc., Santa Clara, CA (US)

(21) Appl. No.: 19/081,236

(22) Filed: Mar. 17, 2025

(51) Int. Cl. H10D 84/01; H10D 30/00; H10D 30/01; H10D 30/43; H10D 62/00; H10D 62/10; H10D 62/13; H10D 62/60; H10D 62/83; H10D 62/832; H10D 62/834; H10D 84/83

(52) U.S. Cl. CPC H10D 84/013; H10D 30/014; H10D 30/019; H10D 62/021; H10D 62/102; H10D 62/60; H10D 62/83; H10D 62/832; H10D 62/834; H10D 30/43; H10D 30/502; H10D 62/121; H10D 62/151; H10D 84/832

(57) ABSTRACT

Methods of manufacturing semiconductor devices are described. The methods include etching a portion of a silicon layer of a transistor to form an opening adjacent to the silicon layer, the silicon layer extending between a source region and a drain region on a substrate; forming a p-type epitaxial liner layer in the opening and on the transistor in the source region and the drain region; an forming an n-type epitaxial gapfill layer on the p-type epitaxial liner layer to form a source and a drain.

### TECHNICAL FIELD

Embodiments of the present disclosure pertain to the field of semiconductor devices and semiconductor device manufacturing. More particularly, embodiments of the disclosure relate to epitaxial layer deposition for semiconductor devices.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width.

Examples of transistor device structures include a planar field-effect transistor (FET), a fin field effect transistor (FinFET), which is characterized by a fin-shaped channel region that greatly increases the size of the transistor without significantly increasing the footprint of the transistor, and a gate-all-around (GAA) transistor. Logic gate performance is related to the characteristics of the materials used as well as the thickness and area of the structural layers. However, as some gate characteristics are adjusted to accommodate device scaling, challenges arise.

It has been observed that continuous gate length scaling in advanced logic nodes have degraded threshold voltage (Vₜ), drain-induced barrier lowering (DIBL), and leakage, which are short-channel effects. Short-channel effects occur when the channel length is the same order of magnitude as the depletion-layer widths of the source and drain junction. Short-channel effects reduce the transistor's threshold voltage (Vₜ) at higher drain voltages. Due to short-channel effects, the gate starts to lose control over the channel and electric field from the source and drain start to interfere with and influence channel potential.

In planar FET transistor device structures, for example, an angled implant, known in the art as a “halo implant,” was used at the source-channel junction and the drain-channel junction, respectively, to reduce source and drain influence on channel potential. In FinFET and GAA transistor device structures, the halo implant was eliminated due to high aspect ratio structures. Therefore, with continuous gate-length scaling, transistor short-channel performance continues to degrade.

Accordingly, there is a need for improved methods that reduce short-channel effects.

### SUMMARY

One or more embodiments of the disclosure are directed to methods of manufacturing a semiconductor device. The method includes: etching a portion of a silicon layer of a transistor to form an opening adjacent to the silicon layer, the silicon layer extending between a source region and a drain region on a substrate; forming a p-type epitaxial liner layer in the opening and on the transistor in the source region and the drain region; and forming an n-type epitaxial gapfill layer on the p-type epitaxial liner layer to form a source and a drain.

Additional embodiments of the disclosure are directed to a method of manufacturing a semiconductor device. The method includes: etching a portion of a silicon layer of a transistor to form an opening adjacent to the silicon layer, the silicon layer extending between a source region and a drain region on a substrate; forming a p-type epitaxial liner layer in the opening and on the transistor in the source region and the drain region, the p-type epitaxial liner layer comprising silicon (Si) or silicon germanium (SiGe) and a dopant; and forming a n-type epitaxial gapfill layer on the p-type epitaxial liner layer to form a source and a drain.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate one or more embodiments of this disclosure and are therefore not to be considered limiting of its scope, for the disclosure may admit to other equally effective embodiments.

To facilitate understanding, identical reference numerals have been used, unless indicated otherwise to designate identical elements that are common to the Figures. It is contemplated that elements of one embodiment may be beneficially incorporated in other embodiments without further recitation.

FIG. 1 illustrates a process flow diagram of a method of forming a semiconductor device according to one or more embodiments;

FIG. 2 illustrates a cross-sectional view of a substrate according to one or more embodiments;

FIG. 3 illustrates a cross-sectional view of a substrate according to one or more embodiments;

FIG. 4 illustrates a cross-sectional view of a substrate according to one or more embodiments;

FIG. 5 illustrates a cross-sectional view of a substrate according to one or more embodiments;

FIG. 6 illustrates a cross-sectional view of a substrate according to one or more embodiments;

FIG. 7 illustrates a cross-sectional view of a substrate according to one or more embodiments;

FIG. 8 illustrates a cross-sectional view of a substrate according to one or more embodiments;

FIG. 9 illustrates a cross-sectional view of a substrate according to one or more embodiments;

FIG. 10 illustrates a cross-sectional view of a substrate according to one or more embodiments;

FIG. 11 illustrates a cross-sectional view of a substrate according to one or more embodiments; and

FIG. 12 illustrates a cross-sectional view of a substrate according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to another element(s) or as illustrated in the Figures. It will be understood that the spatially relative terms are intended to encompass different orientations of a substrate or a device, such as a semiconductor device, in use or operation in addition to the orientation depicted in the Figures. For example, if the substrate or device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular element, structure, material, or characteristic described in connection with the embodiment is included in at least one embodiment of the disclosure. Thus, the instances in which the phrases such as “in one or more embodiments,” “in certain embodiments,” “in one embodiment,” “in some embodiments,” or “in an embodiment” used in various places throughout this specification are not necessarily referring to the same embodiment of the disclosure. In one or more embodiments, the particular elements, structures, materials, or characteristics are combined in any suitable manner.

In the above description and illustrations and following description, numerous specific details, such as specific materials, chemistries, dimensions of the elements, etc., are set forth in order to provide thorough understanding of one or more of the embodiments of the present disclosure. It will be apparent, however, to one of ordinary skill in the art that one or more embodiments of the present disclosure may be practiced without these specific details. In other instances, semiconductor fabrication processes, techniques, materials, equipment, etc., have not been described in great detail to avoid unnecessarily obscuring this description.

Those of ordinary skill in the art, with the included description, will be able to implement appropriate functionality without undue experimentation.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which layer or film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor,” “reactant,” “reactive gas,” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source regions and drain regions. In one or more embodiments, the source region and drain region each independently include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode FETs generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of FET. A MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p-type or n-type, but they are both of the same type, and of opposite type to the body region. The source and drain (unlike the body) are highly doped as signified by a “+” sign after the type of doping.

If the MOSFET is an n-channel or nMOS FET, then the source and drain are n+regions and the body is a p region. If the MOSFET is a p-channel or pMOS FET, then the source and drain are p+regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. The fin-shaped channel region greatly increases the size of the transistor without significantly increasing the footprint of the transistor. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanosheets, nanowires nanoslabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer. One or more embodiments of the disclosure are directed to methods of forming transistors that may be used in FEOL processes.

In one or more embodiments, transistors are fabricated using a standard process flow. One or more of the Figures illustrate a part or a step of a multi-step fabrication process of a semiconductor device, particularly relating to epitaxial liner layer deposition.

It has been observed that continuous gate length scaling in advanced logic nodes have degraded threshold voltage (Vₜ), drain-induced barrier lowering (DIBL), and leakage, which are short-channel effects. Short-channel effects occur when the channel length is the same order of magnitude as the depletion-layer widths of the source and drain junction. Short-channel effects reduce the transistor's threshold voltage (Vₜ) at higher drain voltages. Due to short-channel effects, the gate starts to lose control over the channel and electric field from the source and drain start to interfere with and influence channel potential.

In planar FET transistor device structures, for example, an angled implant, known in the art as a “halo implant,” was used at the source-channel junction and the drain-channel junction, respectively, to reduce source and drain influence on channel potential. In FinFET and GAA transistor device structures, the halo implant was eliminated due to high aspect ratio structures. Therefore, with continuous gate-length scaling, transistor short-channel performance continues to degrade.

Embodiments of the present disclosure advantageously provide methods that are configured to reduce short-channel effects. Some embodiments advantageously provide methods that are configured to reduce short-channel effects in FinFET transistor device structures. Some embodiments advantageously provide methods that are configured to reduce short-channel effects in GAA transistor device structures.

It is thought that the source and the drain of current GAA NMOS structures include a first n-type epitaxial liner layer and a second n-type epitaxial layer formed on the first n-type epitaxial liner layer. The first n-type epitaxial liner layer comprises silicon (Si) and an n-type dopant, e.g., phosphorous (P) or arsenic (As). In many current GAA NMOS structures, the dopant has a concentration of 1e20 cm⁻³ to 5e20 cm⁻³ in the first n-type epitaxial liner layer. The second n-type epitaxial layer comprises silicon (Si) and an n-type dopant, e.g., phosphorous (P) or arsenic (As). In many current GAA NMOS structures, the dopant has a concentration of 7e20 cm⁻³ to 2e21 cm⁻³ in the second n-type epitaxial layer. As a result, in these current GAA NMOS structures, there is a large amount of phosphorous diffusion from the source region/drain region into the channel, which is evidenced by short-channel effects. It is thought that the short-channel effects will be even more prominent with gate-length scaling for next generation logic nodes.

Embodiments of the present disclosure are directed to epitaxial liner layer deposition for NMOS structures, including forming a p-type epitaxial liner layer and forming an n-type epitaxial gapfill layer on the p-type epitaxial liner layer. Advantageously, embodiments of the disclosure directed epitaxial liner layer deposition for NMOS structures, including forming a p-type epitaxial liner layer and forming an n-type epitaxial gapfill layer on the p-type epitaxial liner layer, are configured to reduce short-channel effects. Advantageously, using the p-type epitaxial liner layer, i.e., a layer that does not include phosphorous (P), provides reduced short-channel effects caused by phosphorous diffusion as in many current GAA NMOS structures.

Advantageously, embodiments of the disclosure directed epitaxial liner layer deposition for NMOS structures, including forming a p-type epitaxial liner layer and forming an n-type epitaxial gapfill layer on the p-type epitaxial liner layer, are configured to provide a DIBL improvement in a range of from 10 mV/V to 15 mV/V relative to current GAA NMOS structures. Advantageously, embodiments of the disclosure directed epitaxial liner layer deposition for NMOS structures, including forming a p-type epitaxial liner layer and forming an n-type epitaxial gapfill layer on the p-type epitaxial liner layer, are configured to an increase in threshold voltage (Vₜ) relative to current GAA NMOS structures.

The processes described herein may be integrated and performed in any suitable processing system. In one or more embodiments, the method 10 is performed in situ in an integrated processing system. The processing system may include process chambers for fabricating the semiconductor device, such as chambers configured for etching, deposition, epitaxial deposition, atomic layer deposition (ALD), physical vapor deposition (PVD), chemical vapor deposition (CVD), oxidation, or any other suitable chamber used for the fabrication of a semiconductor device.

The embodiments of the disclosure are described by way of the Figures, which illustrate semiconductor devices (e.g., transistors) and methods of manufacturing transistors in accordance with one or more embodiments of the disclosure. The processes shown are merely illustrative possible uses for the disclosed processes, and the skilled artisan will recognize that the disclosed processes are not limited to the illustrated applications.

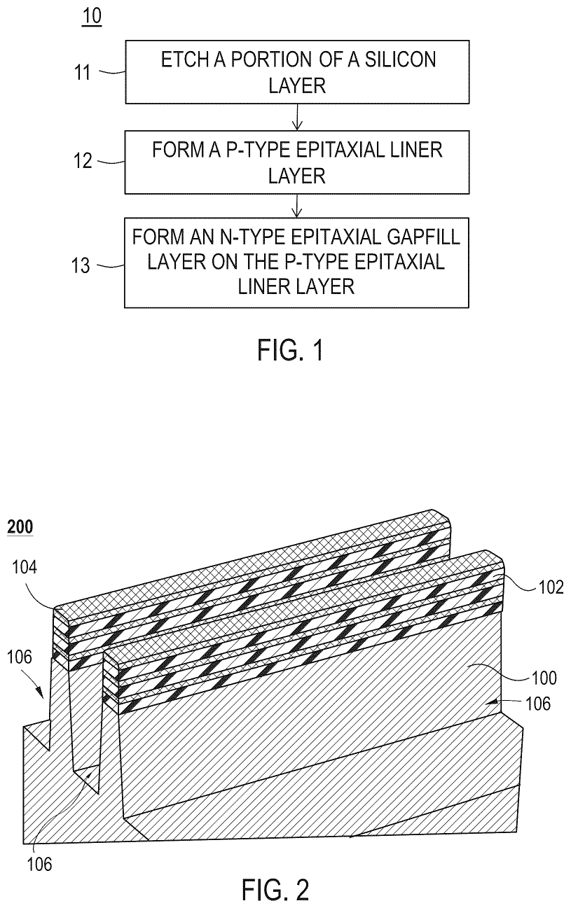

FIG. 1 illustrates a process flow diagram of a method 10 of manufacturing a semiconductor device 200 in accordance with one or more embodiments of the present disclosure. The method 10 may be part of a multi-step semiconductor device fabrication process. In one or more embodiments, the method 10 is performed in situ in an integrated processing system. The method 10 is described below with respect to FIGS. 2-12, which depicts various stages of processing a substrate 100 to form the semiconductor device 200 in accordance with one or more embodiments of the present disclosure.

FIGS. 2-9 illustrate stages of manufacturing the semiconductor device 200 as part of a baseline process. Stated differently, the processes illustrated in and description associated with FIGS. 2-9 will be understood by a person of ordinary skill in the art of semiconductor manufacturing.

The substrate 100 as used herein refers to any substrate or material surface formed on a substrate upon which layer or film processing is performed during a fabrication process. In one or more embodiments, the substrate 100 comprises silicon.

In one or more embodiments, a plurality of alternating layers of silicon 104 and silicon germanium 102 are epitaxially formed on the substrate 100. In one or more embodiments, the silicon germanium layer 102 is formed directly on a top surface the substrate 100, followed by the silicon layer 104 directly on the silicon germanium layer 102, and so on. The plurality of alternating layers of silicon 104 and silicon germanium 102 can include any suitable number of respective layers.

As will be understood and appreciate by the skilled artisan, the silicon layers 104 may be referred to as “nanosheet channel layers” and the silicon germanium layers 102 may referred to as “nanosheet release layers.”

The silicon layers 104 may have any suitable thickness. The silicon germanium layers 102 may have any suitable thickness. In one or more embodiments, the silicon layers 104 have a thickness in a range of from 5 nm to 15 nm. In one or more embodiments, the silicon layers 104 have a thickness of 6 nm. In one or more embodiments, the silicon germanium layers 102 have a thickness in a range of from 5 nm to 15 nm. In one or more embodiments, the silicon germanium layers 102 have a thickness of 8 nm.

In one or more embodiments, the plurality of alternating layers of silicon 104 and silicon germanium 102 and a portion of the substrate 100 are etched. In one or more embodiments, etching the plurality of alternating layers of silicon 104 and silicon germanium 102 and the portion of the substrate forms a plurality of trenches 106, as shown in FIG. 2.

The plurality of trenches 106 have a depth that extends from a bottom surface of the plurality of alternating layers of silicon 104 and silicon germanium 102 into the substrate 100.

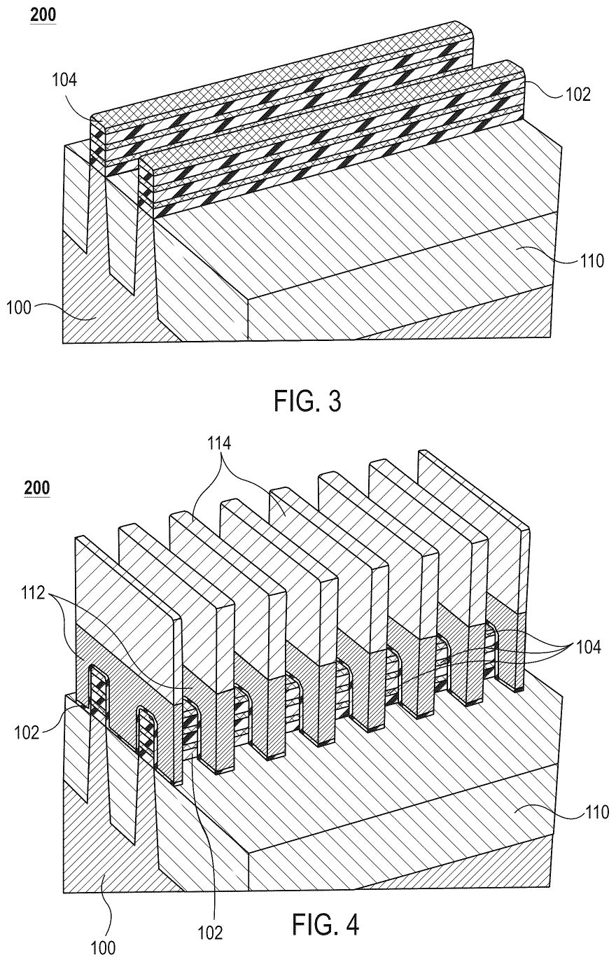

In FIG. 3, each of the plurality of trenches 106 are filled with an oxide material 110. The oxide material 110 may be deposited in each of the plurality of trenches 106 using any suitable deposition technique. In one or more embodiments, the oxide material 110 is deposited directly on the substrate 100. In one or more embodiments, the oxide material 110 is deposited directly on the substrate 100 by chemical vapor deposition (CVD). In one or more embodiments, the plurality of alternating layers of silicon 104 and silicon germanium 102 do not contact the oxide material 110. In some embodiments, one or more of the plurality of alternating layers of silicon 104 and silicon germanium 102 contact the oxide material 110. In some embodiments, the layer of silicon germanium 102 nearest the substrate 100 contacts the oxide material 110.

The oxide material 110 can be any suitable oxygen-containing material. In one or more embodiments, the oxide material 110 comprises silicon oxide. The oxide material 110 is configured to isolate each of the plurality of trenches 106 from one another.

FIG. 4 illustrates a dummy gate structure 112 formed on top of the plurality of alternating layers of silicon 104 and silicon germanium 102. The dummy gate structure 112 may be formed using any suitable deposition and etching process. In one or more embodiments, the dummy gate structure 112 comprises one or more of tungsten (W), cobalt (Co), molybdenum (Mo), ruthenium (Ru), titanium nitride (TiN), tantalum nitride (TaN), titanium aluminum (TiAl), or doped or undoped polysilicon.

The dummy gate structure 112 defines a channel region of the semiconductor device. In one or more embodiments, the channel region separates the dummy gate structure 112 from an adjacent dummy gate structure.

FIG. 4 also illustrates a capping layer 114 on the dummy gate structure 112. In one or more embodiments, the capping layer 114 is formed directly on the dummy gate structure.

The capping layer 114 may include any suitable insulating material. In one or more embodiments, the capping layer 114 comprises one or more of silicon nitride, silicon oxide, silicon oxynitride, or silicon carbide. In one or more embodiments, the capping layer 114 comprises silicon nitride.

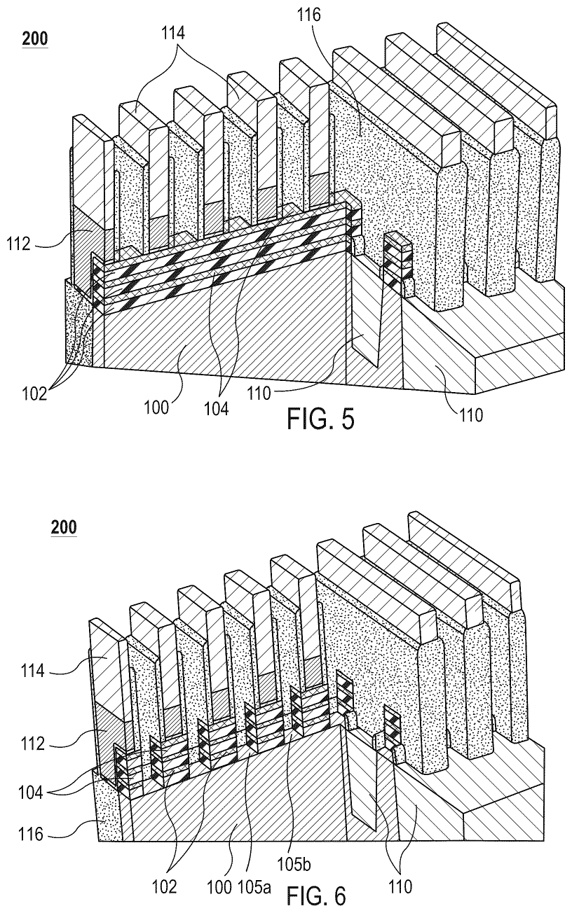

FIG. 5 illustrates sidewall spacers 116 formed on the dummy gate structure 112 and at least a portion of the capping layer 114. In one or more embodiments, the sidewall spacers 116 cover the dummy gate structure 112 in its entirety. In one or more embodiments, the sidewall spacers 116 insulate the dummy gate structure 112 from an adjacent dummy gate structure. The sidewall spacers 116 may be formed by any suitable deposition technique.

The sidewall spacers 116 may include any suitable insulating material. In one or more embodiments, the sidewall spacers 116 comprise one or more of silicon nitride, silicon oxide, silicon oxynitride, or silicon carbide.

The sidewall spacers 116 may have any suitable thickness. In one or more embodiments, the sidewall spacers 116 have a thickness of about 5 nm.

FIG. 6 illustrates a source region 105a and a drain region 105b formed by etching the channel region. The source region 105a and the drain region 105b are formed adjacent (i.e., on either side) of the plurality of alternating layers of silicon 104 and silicon germanium 102.

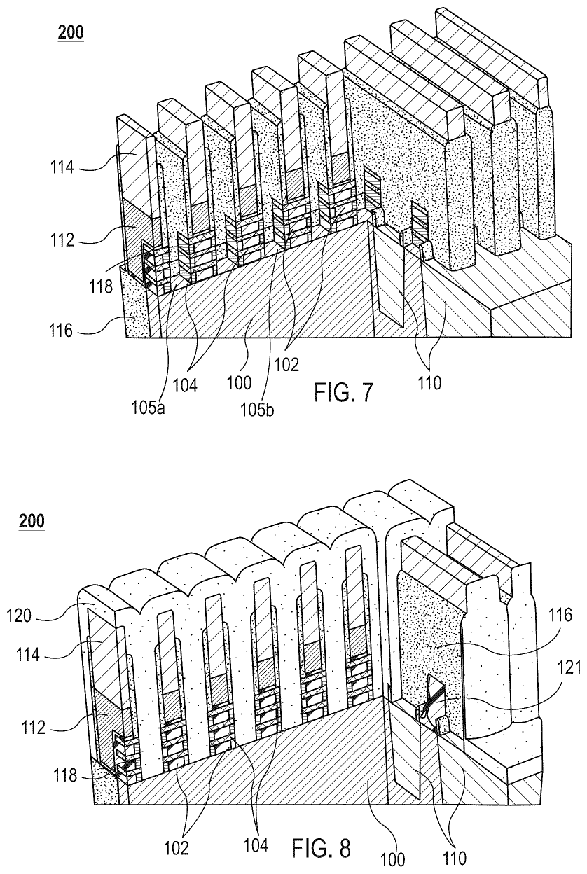

FIG. 7 illustrates inner spacers 118 formed on the plurality of alternating layers of silicon 104 and silicon germanium 102. The inner spacers 118 may be formed by any suitable deposition technique.

The inner spacers 118 may include any suitable insulating material. In one or more embodiments, the inner spacers comprise one or more of silicon nitride, silicon oxide, silicon oxynitride, or silicon carbide.

The inner spacers 118 may have any suitable thickness. In one or more embodiments, the inner spacers 118 have a thickness of about 5 nm.

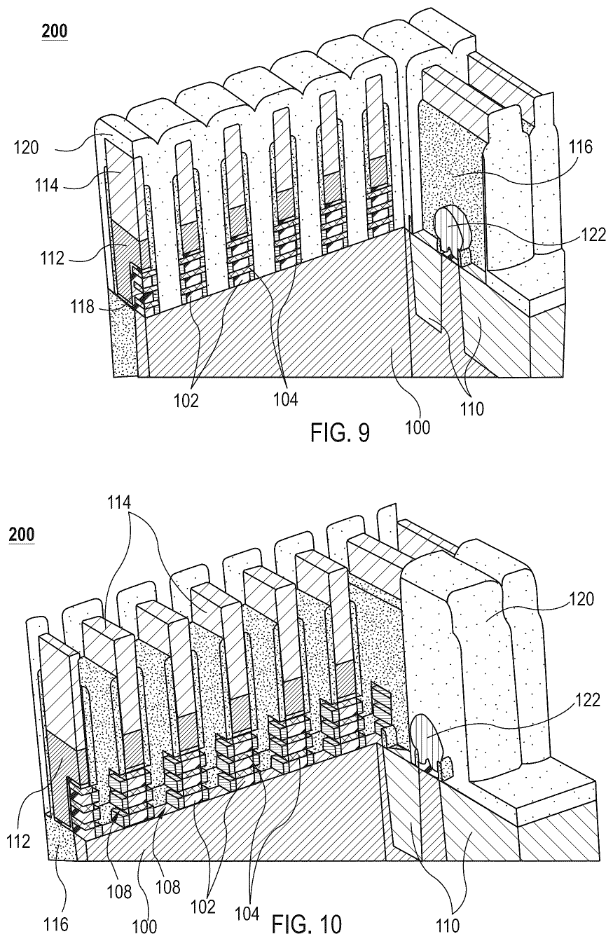

FIGS. 8 and 9 illustrate an epitaxial deposition process to form a PMOS structure. In FIGS. 8 and 9, a protective layer 120 is formed on at least a portion of the structure on the substrate 100. In one or more embodiments, the protective layer 120 is formed on one or more of the plurality of alternating layers of silicon 104 and silicon germanium 102, the dummy gate structure 112, the capping layer 114, the sidewall spacers 116, and the inner spacers 118. In one or more embodiments, the protective layer 120 comprises a hard mask material. In one or more embodiments, the protective layer 120 is configured to prevent deposition on one or more of the plurality of alternating layers of silicon 104 and silicon germanium 102, the dummy gate structure 112, the capping layer 114, the sidewall spacers 116, and the inner spacers 118.

FIG. 8 illustrates formation of a p-type source/drain epitaxial liner layer (i.e., a p-type epitaxial liner layer 121). In some embodiments, the p-type epitaxial liner layer 121 is formed by an epitaxial deposition process. The p-type epitaxial liner layer 121 comprises silicon germanium (SiGe) and a dopant.

In one or more embodiments, the dopant comprises a p-type dopant. In one or more embodiments, the p-type dopant is boron (B). In one or more embodiments, the p-type dopant is gallium (Ga). In one or more embodiments, the p-type dopant is arsenic (As).

The p-type epitaxial liner layer 121 may have any suitable germanium content. In one or more embodiments, the p-type epitaxial liner layer 121 has a germanium content of about 10 % on an atomic basis.

The dopant may have any suitable concentration in the p-type epitaxial liner layer 121. In one or more embodiments, the dopant has a concentration of 2e20 cm⁻³. In one or more embodiments, the dopant comprises boron (B) and has a concentration of 2e20 cm⁻³.

FIG. 9 illustrates formation of a p-type source/drain epitaxial gapfill layer (i.e., a p-type epitaxial gapfill layer 122) directly on the p-type epitaxial liner layer 121. In some embodiments, the p-type epitaxial gapfill layer 122 is formed by an epitaxial deposition process.

The p-type epitaxial gapfill layer 122 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the p-type epitaxial gapfill layer 122 on an atomic basis, comprises seams and/or voids. Advantageously, in one or more embodiments, the p-type epitaxial gapfill layer 122 is free of seams and/or voids.

The p-type epitaxial gapfill layer 122 comprises silicon germanium (SiGe) and a dopant. In one or more embodiments, the dopant comprises a p-type dopant. In one or more embodiments, the p-type dopant is boron (B). In one or more embodiments, the p-type dopant is gallium (Ga). In one or more embodiments, the p-type dopant is arsenic (As).

The p-type epitaxial gapfill layer 122 may have any suitable germanium content. In one or more embodiments, the p-type epitaxial gapfill layer 122 has a germanium content of about 50 % on an atomic basis.

The dopant may have any suitable concentration in the p-type epitaxial gapfill layer. In one or more embodiments, the dopant has a concentration of 1e21 cm⁻³. In one or more embodiments, the dopant comprises boron (B) and has a concentration of 2e20 cm⁻³.

In FIG. 10, the protective layer 120 is formed on one or more of the p-type source/drain epitaxial liner layer (i.e., the p-type epitaxial liner layer 121), or the p-type source/drain epitaxial gapfill layer (i.e., a p-type epitaxial gapfill layer 122). Referring to FIG. 10, in one or more embodiments, the protective layer 120 is configured to protect the PMOS structure formed in FIGS. 8 and 9 during the method 10.

Referring to the method 10 shown in FIG. 1, FIG. 10 also illustrates etching a portion of the silicon layers (of the plurality of alternating silicon 104 and silicon germanium layers 102) of the transistor (i.e., semiconductor device 200) to form an opening 108 adjacent to the silicon layer 104.

The etching process can be any suitable etching process. In one or more embodiments, the etching process is an isotropic etching process. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric acid or hydrogen peroxide.

The silicon layer 104 extends between the source region 105a and the drain region 105b on the substrate 100.

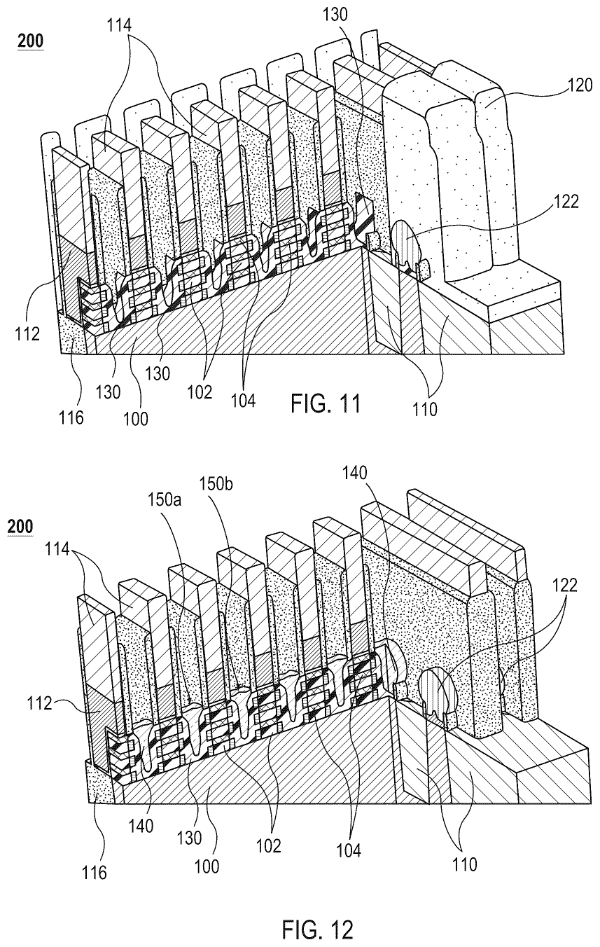

FIGS. 11 and 12 illustrate an epitaxial deposition process to form an NMOS structure. FIG. 11 illustrates formation of a p-type epitaxial liner layer 130 in the opening 108 and on the transistor (i.e., semiconductor device 200) in the source region 105a and the drain region 105b. In one or more embodiments, the p-type epitaxial liner layer 130 fills a portion of the opening 108. In some embodiments, the p-type epitaxial liner layer 130 is formed by an epitaxial deposition process.

The p-type epitaxial liner layer 130 comprises, consists essentially of, or consists of silicon (Si) or silicon germanium (SiGe) and a dopant.

In one or more embodiments, the dopant comprises a p-type dopant. In one or more embodiments, the p-type dopant is boron (B). In one or more embodiments, the p-type dopant is gallium (Ga). In one or more embodiments, the p-type dopant is arsenic (As).

The dopant may have any suitable concentration in the p-type epitaxial liner layer comprising, consisting essentially of, or consisting of silicon (Si) or silicon germanium (SiGe) and the dopant. In one or more embodiments, the dopant has a concentration in a range of from 1e19 cm⁻³ to 3e19 cm⁻³. In one or more embodiments, the dopant comprises boron (B) and has a concentration in a range of from 1e19 cm⁻³ to 3e19 cm⁻³.

In one or more embodiments, the p-type epitaxial liner layer 130 comprises, consists essentially of, or consists of silicon (Si) and the dopant comprising boron (B) and having a concentration in a range of from 1e19 cm⁻³ to 3e19 cm⁻³. In one or more embodiments, the p-type epitaxial liner layer 130 comprises, consists essentially of, or consists of silicon germanium (SiGe) and the dopant comprising boron (B) and having a concentration in a range of from 1e19 cm⁻³ to 3e19 cm⁻³.

FIG. 12 illustrates formation of an n-type epitaxial gapfill layer 140 directly on the p-type epitaxial liner layer 130. In some embodiments, the n-type epitaxial gapfill layer 140 is formed by an epitaxial deposition process. In one or more embodiments, the n-type epitaxial gapfill layer 140 on the p-type epitaxial liner layer 130 fills the opening 108.

The n-type epitaxial gapfill layer 140 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the n-type epitaxial gapfill layer 140 on an atomic basis, comprises seams and/or voids. Advantageously, in one or more embodiments, the n-type epitaxial gapfill layer 140 is free of seams and/or voids.

The n-type epitaxial gapfill layer 140 comprises, consists essentially of, or consists of silicon (Si) and a dopant. In one or more embodiments, the dopant comprises an n-type dopant. In one or more embodiments, the n-type dopant is phosphorous (P).

The dopant may have any suitable concentration in the n-type epitaxial gapfill layer 140. In one or more embodiments, the dopant has a concentration of 1e21 cm⁻³. In one or more embodiments, the dopant comprises phosphorus (P) and has a concentration of 1e21 cm⁻³.

In FIG. 12, the n-type epitaxial gapfill layer 140 formed directly on the p-type epitaxial liner layer 130 forms a source 150a and a drain 150b. As will be understood and appreciate by the skilled artisan, the source 150a and the drain 150b, respectively, can be on either side of the silicon layer 104 once the opening 108 adjacent the silicon layer 104 has been formed, and the disclosure is not limited to the source 150a and the drain 150b being on one particular side of the silicon layer 104. In FIG. 12, in one or more embodiments, the protective layer 120 is shown as being removed. In FIG. 12, in one or more embodiments, the protective layer 120 is not present on the PMOS structure or the NMOS structure.

Embodiments of the disclosure are directed to a non-transitory computer readable medium including instructions that, when executed by a controller of a processing system to perform the operations of any of the methods described herein.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of manufacturing a semiconductor device, the method comprising:
etching a portion of a silicon layer of a transistor to form an opening adjacent to the silicon layer, the silicon layer extending between a source region and a drain region on a substrate;
forming a p-type epitaxial liner layer in the opening and on the transistor in the source region and the drain region; and
forming an n-type epitaxial gapfill layer on the p-type epitaxial liner layer to form a source and a drain.

2. The method of claim 1, wherein the p-type epitaxial liner layer comprises silicon (Si) or silicon germanium (SiGe) and a dopant.

3. The method of claim 2, wherein the dopant has a concentration in a range of from 1e19 cm⁻³ to 3e19 cm⁻³.

4. The method of claim 3, wherein the dopant comprises boron (B).

5. The method of claim 4, wherein the n-type epitaxial gapfill layer comprises silicon and a dopant.

6. The method of claim 5, wherein the dopant has a dopant concentration of about 1e21 cm⁻³.

7. The method of claim 6, wherein the dopant comprises phosphorous (P).

8. The method of claim 1, wherein the semiconductor device is a logic device or a memory device.

9. The method of claim 1, wherein the transistor is a planar field-effect transistor (FET), a fin field-effect transistor (FinFET), or a gate-all-around (GAA) transistor.

10. The method of claim 9, wherein the transistor is a gate-all-around (GAA) transistor, comprising a superlattice structure including alternating layers of the silicon layer and a sacrificial layer.

11. The method of claim 1, performed in situ in an integrated processing system.

12. A method of manufacturing a semiconductor device, the method comprising:
etching a portion of a silicon layer of a transistor to form an opening adjacent to the silicon layer, the silicon layer extending between a source region and a drain region on a substrate;
forming a p-type epitaxial liner layer in the opening and on the transistor in the source region and the drain region, the p-type epitaxial liner layer comprising silicon (Si) or silicon germanium (SiGe) and a dopant; and
forming a n-type epitaxial gapfill layer on the p-type epitaxial liner layer to form a source and a drain.

13. The method of claim 12, wherein the dopant comprises boron (B) and has a concentration in a range of from 1e19 cm⁻³ to 3e19 cm⁻³.

14. The method of claim 12, wherein the n-type epitaxial gapfill layer comprises silicon and a dopant.

15. The method of claim 14, wherein the dopant has a dopant concentration of about 1e21 cm⁻³.

16. The method of claim 15, wherein the dopant comprises phosphorous (P).

17. The method of claim 12, wherein the semiconductor device is a logic device or a memory device.

18. The method of claim 12, wherein the transistor is a planar field-effect transistor (FET), a fin field-effect transistor (FinFET), or a gate-all-around (GAA) transistor.

19. The method of claim 18, wherein the transistor is a gate-all-around (GAA) transistor, comprising a superlattice structure including alternating layers of the silicon layer and a sacrificial layer.

20. The method of claim 12, performed in situ in an integrated processing system.
